(19) United States
(12) Patent Application Publication
(10) Pub. No.: US 2025/0266198 A1
(43) Pub. Date: Aug. 21, 2025

(54) YPtBi 1:1:1 Composition Design Using Krypton Sputtering in Deposition Systems

(71) Applicant: Western Digital Technologies, Inc., San Jose, CA (US)

(72) Inventors: Quang LE, San Jose, CA (US); Brian R. YORK, San Jose, CA (US); Cherngye HWANG, San Jose, CA (US); Michael A. GRIBELYUK, Stamford, CT (US); Hisashi TAKANO, Fujisawa-shi (JP)

(73) Assignee: Western Digital Technologies, Inc., San Jose, CA (US)

(21) Appl. No.: 19/011,206

(22) Filed: Jan. 6, 2025

Related U.S. Application Data
(60) Provisional application No. 63/554,533, filed on Feb. 16, 2024.

(51) Int. Cl. H01F 10/32; H10B 61/00; H10N 50/01; H10N 50/10; H10N 50/85

(52) U.S. Cl. CPC H01F 10/329; H10B 61/20; H10N 50/01; H10N 50/10; H10N 50/85

(57) ABSTRACT

The present disclosure generally relates to topological semi-metal (TSM) based spin-orbit torque (SOT) devices, and methods of forming a TSM layer. The TSM layer of the SOT device comprises YPtBi having a 1:1:1 stoichiometry. The YPtBi has a density between about 9.7 g/cc to about 11.2 g/cc. Kr, Ar, or Xe gas is used to sputter the YPtBi to form the YPtBi layer or film. Trace amounts of Kr, Ar, or Xe are detectable in the YPtBi layer, where the YPtBi layer comprises about 1% of Kr, Ar, or Xe. One or more targets comprising YPtBi; YPt and Bi; PtBi and Y; Y, Pt, and Bi; or YBi and Pt can be used when forming the YPtBi layer. In embodiments where two targets are used to form the YPtBi layer, different amounts of power may be applied to each target.

### CROSS-REFERENCE TO RELATED APPLICATIONS

This application claims benefit of U.S. provisional patent application Ser. No. 63/554,533, filed Feb. 16, 2024, which is herein incorporated by reference.

### BACKGROUND OF THE DISCLOSURE

### Field of the Disclosure

Embodiments of the present disclosure generally relate to spin-orbit torque (SOT) device comprising a topological semi-metal (TSM) layer.

### Description of the Related Art

YPtBi layers are narrow band gap topological semi-metals having both giant spin Hall effect and high electrical conductivity. YPtBi is a material that has been proposed in various spin-orbit torque (SOT) device applications, such as for a spin Hall layer for magnetoresistive random access memory (MRAM) devices, magnetic recording read heads, sensors, and energy-assisted magnetic recording (EAMR) magnetic recording heads. However, utilizing YPtBi materials in commercial SOT applications can present several obstacles. For example, YPtBi materials require specific buffer layers and/or interlayers, as well as optimal processing conditions, to achieve the desired orientation.

Therefore, there is a need for an improved SOT device utilizing TSM layer(s) having a desired crystal orientation.

### SUMMARY OF THE DISCLOSURE

The present disclosure generally relates to topological semi-metal (TSM) based spin-orbit torque (SOT) devices and methods of forming a TSM layer. The TSM layer of the SOT device comprises YPtBi having a 1:1:1 stoichiometry. The YPtBi has a density between about 9.7 g/cc to about 11.2 g/cc. Kr, Ar, or Xe gas is used to sputter the YPtBi to form the YPtBi layer or film. Trace amounts of Kr, Ar, or Xe are detectable in the YPtBi layer, where the YPtBi layer comprises about 1% or less of Kr, Ar, or Xe. One or more targets comprising YPtBi, YPt and Bi, PtBi and Y, or YBi and Pt can be used when forming the YPtBi layer. In embodiments where two targets are used to form the YPtBi layer, different amounts of power may be applied to each target. The YPtBi has a 1:1:1 stoichiometry, which results in a high spin Hall angle being achieved during operation.

In one embodiment, a spin-orbit torque (SOT) device comprises a YPtBi layer having a 1:1:1 stoichiometry, the YPtBi layer having a density between about 9.7 g/cc to about 11.2 g/cc.

In another embodiment, a method of forming a YPtBi film having a 1:1:1 stoichiometry comprises loading a substrate onto a chuck heated to a temperature of about 300° C. to about 600° C. in a deposition chamber, loading a YPt target and a Bi target in the deposition chamber; adjusting a K, Ar, or Xe r gas flow, pressure, and substrate bias of the deposition chamber, and applying power and Kr, Ar, or Xe gas to sputter the YPt target and the Bi target to form a film comprising YPtBi film having a 1:1:1 stoichiometry and a density between about 9.7 g/cc to about 11.2 g/cc.

In yet another embodiment, a method of forming a YPtBi film having a 1:1:1 stoichiometry comprises loading a substrate onto a chuck heated to a temperature of about 300° C. to about 600° C. in a deposition chamber, placing one of the following target combinations in the deposition chamber: 1) a YBi target and a Pt target; 2) a PtBi target and a Bi target; or 3) a Y target, a Pt target, and a Bi target, adjusting a Kr, Ar, or Xe gas flow, pressure, and substrate bias of the deposition chamber, and applying power and Kr, Ar, or Xe gas to sputter the YBi target and the Pt target to form a film comprising YPtBi film having a 1:1:1 stoichiometry and a density between about 9.7 g/cc to about 11.2 g/cc.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic illustration of certain embodiments of a magnetic media drive including a magnetic recording head with a SOT MTJ device.

FIG. 2 is a fragmented, cross-sectional view of certain embodiments of a read/write head with a SOT MTJ device.

FIGS. 3A-3B illustrate spin-orbit torque (SOT) devices, according to various embodiments.

FIGS. 4A-4C illustrate methods of forming YPtBi having a 1:1:1 composition, according to various embodiments.

FIG. 5A illustrates a graph showing the power (W) applied to the Bi target versus the power (W) applied to the YPt target, according to one embodiment.

FIG. 5B illustrates a graph showing the stoichiometry of YPt versus Kr gas flow (sccm), according to one embodiment.

FIG. 6A is a schematic cross-sectional view of a SOT device for use in a MAMR magnetic recording head, such as the MAMR magnetic recording head of the drive of FIG. 1 or other suitable magnetic media drives.

FIGS. 6B-6C are schematic MFS views of certain embodiments of a portion of a MAMR magnetic recording head with a SOT device of FIG. 6A.

FIG. 7 is a schematic cross-sectional view of a SOT MTJ used as a MRAM device.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or the prior art, whether or not a given embodiment achieves a particular advantage is not limiting of the disclosure. Thus, the following aspects, features, embodiments, and benefits are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure generally relates to topological semi-metal (TSM) based spin-orbit torque (SOT) devices, and methods of forming a TSM layer. The TSM layer of the SOT device comprises YPtBi having a 1:1:1 stoichiometry. The YPtBi has a density between about 9.7 g/cc to about 11.2 g/cc. Kr, Ar, or Xe gas is used to sputter the YPtBi to form the YPtBi layer or film. Trace amounts of Kr, Ar, or Xe are detectable in the YPtBi layer, where the YPtBi layer comprises about 1% or less of Kr, Ar, or Xe. One or more targets comprising Y, Bi, and Pt; YPtBi; YPt and Bi; PtBi and Y; or YBi and Pt can be used when forming the YPtBi layer. In embodiments where two targets are used to form the YPtBi layer, different amounts of power may be applied to each target. The YPtBi having a 1:1:1 stoichiometry results in a high spin Hall angle being achieved during operation.

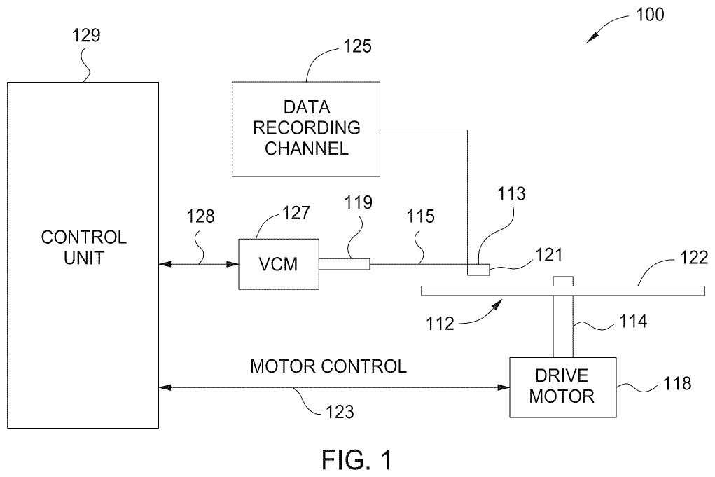

FIG. 1 is a schematic illustration of certain embodiments of a magnetic media drive 100 including a magnetic recording head with a SOT MTJ device. Such a magnetic media drive may be a single drive or comprise multiple drives. For illustration, a single disk drive 100 is shown according to certain embodiments. As shown, at least one rotatable magnetic disk 112 is supported on a spindle 114 and rotated by a drive motor 118. The magnetic recording on each magnetic disk 112 is in the form of any suitable patterns of data tracks, such as annular patterns of concentric data tracks (not shown) on the magnetic disk 112.

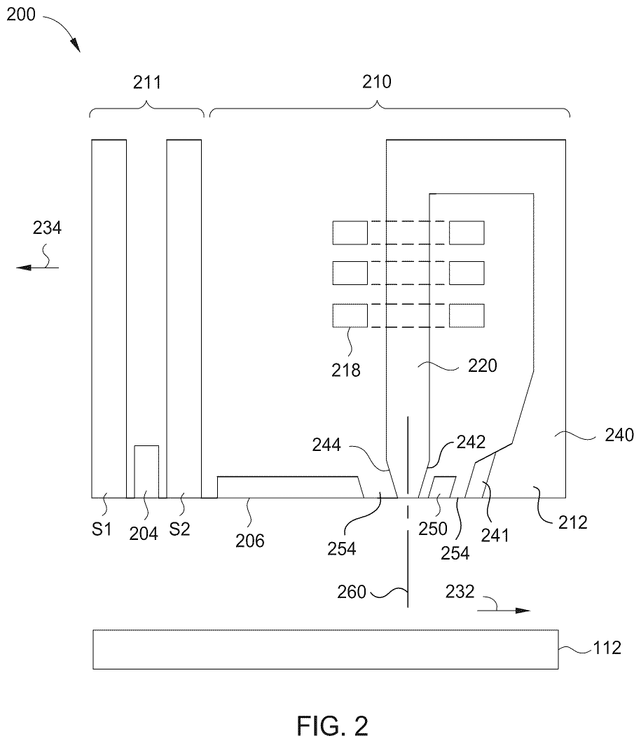

At least one slider 113 is positioned near the magnetic disk 112, and each slider 113 supports one or more magnetic head assemblies 121, including a SOT device. As the magnetic disk 112 rotates, the slider 113 moves radially in and out over the disk surface 122 so that the magnetic head assembly 121 may access different tracks of the magnetic disk 112 where desired data are written. Each slider 113 is attached to an actuator arm 119 by a suspension 115. The suspension 115 provides a slight spring force which biases the slider 113 toward the disk surface 122. Each actuator arm 119 is attached to an actuator means 127. The actuator means 127, as shown in FIG. 2, may be a voice coil motor (VCM). The VCM includes a coil movable within a fixed magnetic field, the direction and speed of the coil movements being controlled by the motor current signals supplied by the control unit 129.

During operation of the disk drive 100, the rotation of the magnetic disk 112 generates an air bearing between the slider 113 and the disk surface 122 which exerts an upward force or lift on the slider 113. The air bearing thus counterbalances the slight spring force of suspension 115, and supports slider 113 off and slightly above the disk surface 122 by a small, substantially constant spacing during regular operation.

The various components of the disk drive 100 are operated by control signals generated by control unit 129, such as access control signals and internal clock signals. The control unit 129 typically comprises logic control circuits, storage means, and a microprocessor. The control unit 129 generates control signals to control various system operations such as drive motor control signals on line 123 and head position and seek control signals on line 128. The control signals on line 128 provide the desired current profiles to move optimally and position slider 113 to the desired data track on disk 112. Write and read signals are communicated to and from write and read heads on the assembly 121 by recording channel 125.

The above description of a typical magnetic media drive and the accompanying illustration of FIG. 1 are for representation purposes only. It should be apparent that magnetic media drives may contain a large number of media, or disks, and actuators, and each actuator may support a number of sliders.

FIG. 2 is a fragmented, cross-sectional side view of certain embodiments of a read/write head 200 having a SOT device. The read/write head 200 faces a magnetic media 112. The read/write head 200 may correspond to the magnetic head assembly 121 described in FIG. 1. The read/write head 200 includes a media facing surface (MFS) 212, such as a gas bearing surface, facing the disk 112, a write head 210, and a magnetic read head 211. As shown in FIG. 2, the magnetic media 112 moves past the write head 210 in the direction indicated by the arrow 232, and the read/write head 200 moves in the direction indicated by the arrow 234.

In some embodiments, the magnetic read head 211 is a magnetoresistive (MR) read head with an MR sensing element 204 located between MR shields S1 and S2. In other embodiments, the magnetic read head 211 is a magnetic tunnel junction (MTJ) read head that includes an MTJ sensing device 204 disposed between MR shields S1 and S2. The magnetic fields of the adjacent magnetized regions in the magnetic disk 112 are detectable by the MR (or MTJ) sensing element 204 as the recorded bits. The SOT device of various embodiments can be incorporated into the read head 211 as the sensing element. An example of a SOT read head is described in a co-pending patent application titled “Topological Insulator Based Spin Torque Oscillator Reader,” U.S. application Ser. No. 17/828,226, filed May 31, 2022, assigned to the same assignee of this application, which is herein incorporated by reference. Another example of a SOT read head is described in co-pending patent applications titled “Non-Localized Spin Valve Reader Hybridized With Spin Orbit Torque Layer,” U.S. application Ser. No. 18/367,877, filed Sep. 13, 2023, and “Non-Localized Spin Valve Multi-Free-Layer Reader Hybridized With Spin Orbit Torque Layers,” U.S. application Ser. No. 18/367,882, filed Sep. 13, 2023, which is herein incorporated by reference.

The write head 210 includes a central or main pole 220, a leading shield 206, a trailing shield 240, an optional spin-orbital torque (SOT) device 250, and a coil 218 that excites the main pole 220. The coil 218 may have a “pancake” structure that winds around a back-contact between the main pole 220 and the trailing shield 240, instead of a “helical” structure shown in FIG. 2. For example, when included, e.g., to achieve a Microwave Assisted Magnetic Recording (MAMR) effect, the SOT device 250 is formed in a gap 254 between the main pole 220 and the trailing shield 240. The main pole 220 includes a trailing taper 242 and a leading taper 244. The trailing taper 242 extends from a location recessed from the MFS 212 to the MFS 212. The leading taper 244 extends from a location recessed from the MFS 212 to the MFS 212. The trailing taper 242 and the leading taper 244 may have the same degree of taper, and the degree of taper is measured with respect to a longitudinal axis 260 of the main pole 220. In some embodiments, the main pole 220 does not include the trailing taper 242 and the leading taper 244. Instead, the main pole 220 includes a trailing side (not shown) and a leading side (not shown), and the trailing side and the leading side are substantially parallel. The main pole 220 may be a magnetic material, such as a FeCo alloy. The leading shield 206 and the trailing shield 240 may comprise magnetic materials, such as a NiFe alloy. In certain embodiments, the trailing shield 240 can include a trailing shield hot seed layer 241. The trailing shield hot seed layer 241 can comprise a high moment sputter material, such as CoFeN, FeXN, or FeX, where X includes at least one of N, Al, Ni, Co, Ta, Re, Ir, Pt, Rh, Ta, Zr, and Ti. In certain embodiments, the trailing shield 240 does not include a trailing shield hot seed layer.

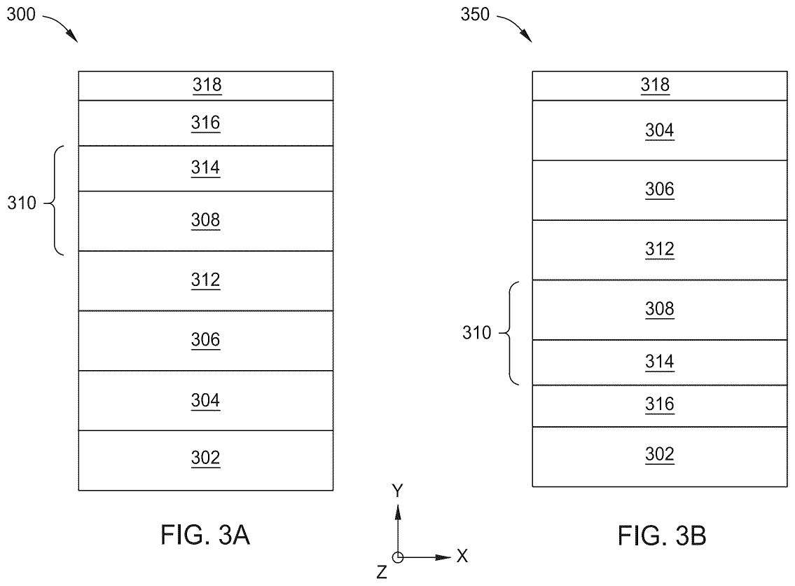

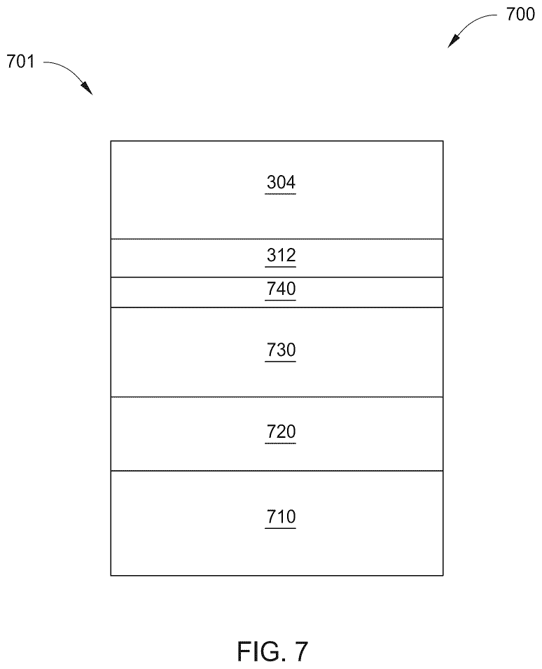

FIGS. 3A-3B illustrate spin-orbit torque (SOT) devices 300, 350, according to various embodiments. The SOT devices 300 and 350 may be used individually in the MAMR recording head of the drive 100 of FIG. 1, in the reader, and/or writer portions of the head 200 of FIG. 2, or other suitable magnetic media drives. The SOT devices 300 and 350 may each individually be an MTJ in sensors or MRAM applications, such as the example MRAM embodiment disclosed in FIG. 7, and spin-charge conversion layers/structures in logic circuits that can be used in artificial intelligence chips. Aspects of the SOT devices 300 and 350 may be used in combination with one another.

The SOT device 300 of FIG. 3A comprises a seed layer 302, a buffer layer 304 disposed over the seed layer 302, a first migration barrier layer 306 disposed over the buffer layer 304, a topological semi-metal (TSM) layer 312 disposed on the first migration barrier layer 306, an interlayer 310 disposed on the TSM layer 312, a ferromagnetic (FM) layer 316 disposed on the interlayer 310, and a cap layer 318 disposed on the FM layer 316. The interlayer 310 comprises a second migration barrier layer 308 disposed on the TSM layer 312 and a sub-interlayer 314 disposed on the second migration barrier layer 308. The first migration barrier layer 306 may comprise a different material than the second migration barrier layer 308. In some embodiments, the second migration barrier layer 308 and the sub-interlayer 314 are considered separate layers, rather than the interlayer 310. The buffer layer 304 may have a (100) orientation, (111) orientation, or a (110) orientation. In some embodiments, the buffer layer 304 comprises the first migration barrier layer 306.

The SOT device 350 of FIG. 3B comprises the seed layer 302, the FM layer 316 disposed on the seed layer 302, the interlayer 310 disposed on the FM layer 316, the TSM layer 312 disposed on the interlayer 310, the first migration barrier layer306 disposed on the TSM layer 312, the buffer layer 304 disposed on the first migration barrier layer 306, and the cap layer 318 disposed on the buffer layer 304. The interlayer 310 comprises the sub-interlayer 314 disposed on the FM layer 316, and the second migration barrier layer 308 disposed between the sub-interlayer 314 and the TSM layer 312. The first migration barrier layer 306 may comprise a different material than the second migration barrier layer 308. The sub-interlayer 314 may have a (100) orientation, a (110) orientation, or a (111) orientation. In some embodiments, the buffer layer 304 comprises the first migration barrier layer 306.

In both SOT devices 300 and 350, the first and second migration barrier layers 306 and 308 are disposed in contact with the TSM layer 312 such that the TSM layer 312 is sandwiched between the first and second migration barrier layers 306 and 308. The buffer layer 304, the interlayer 310, and the cap layer 318 promote epitaxial crystal symmetry growth of the TSM layer 312 while minimizing shunting. The migration barrier layers 306 and 308 further transmit the epitaxial growth and, due to minimal chemical interaction, prevent diffusion of the TSM layer 312 out and prevent materials from diffusing into the TSM layer 312 from the buffer layer 304, the interlayer 310, and the cap layer 318.

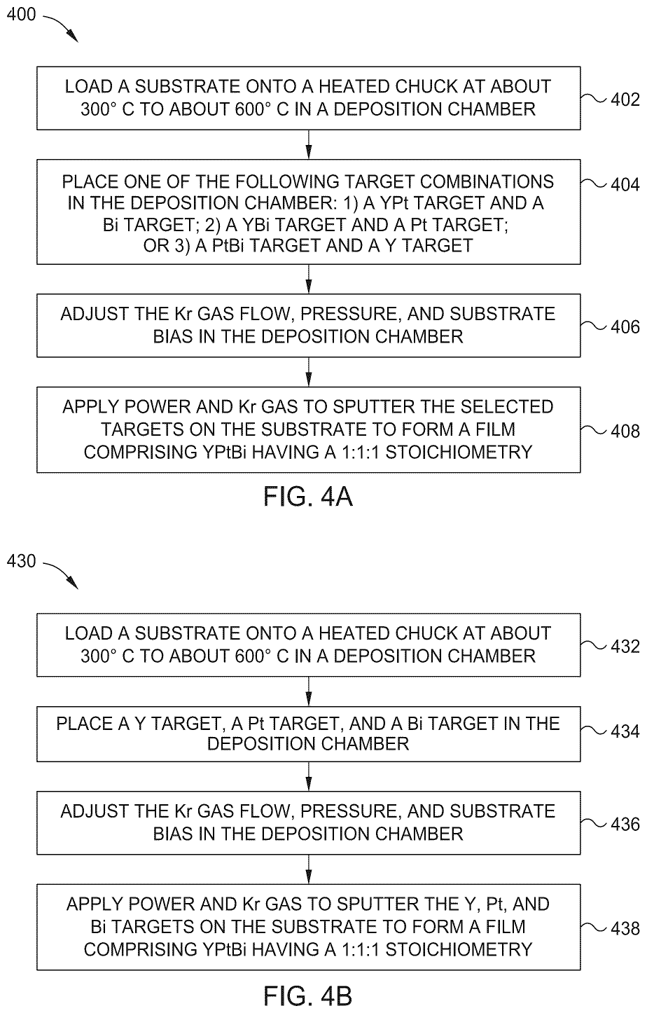

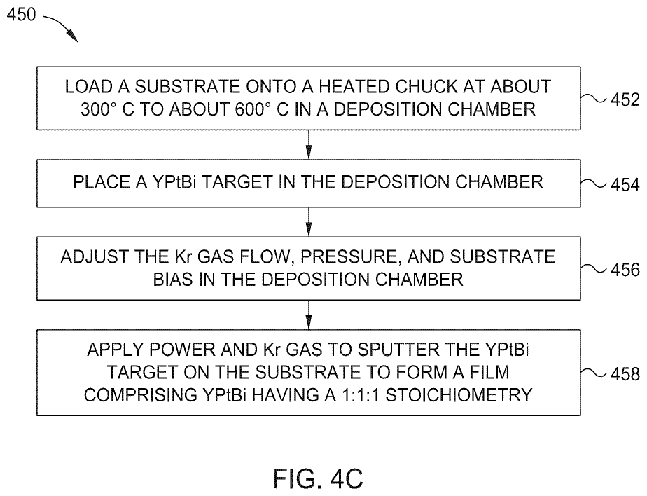

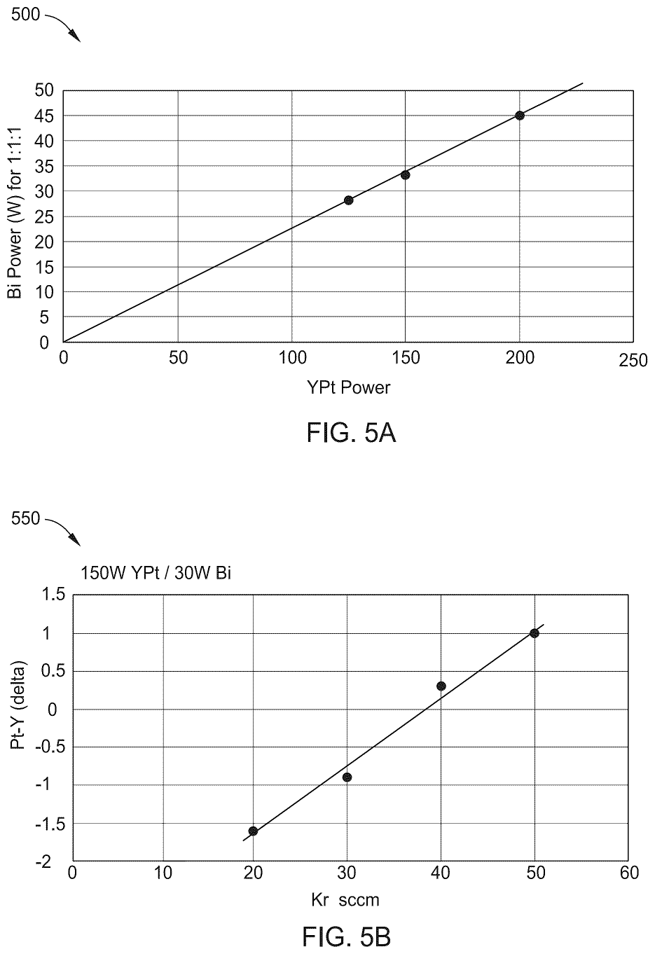

The TSM layer 312 comprises YPtBi having a (100) orientation or a (110) orientation. The YPtBi has a 1:1:1 stoichiometry, and a density of about 9.7 g/cc to about 11.2 g/cc, such as a density of about 11 g/cc or greater. The YPtBi of the TSM layer 312 may comprise trace, detectable amounts of Kr, such as about 1% or less of Kr. The TSM layer 312 comprising YPtBi having a 1:1:1 stoichiometry achieves the highest spin Hall angle during operation. The methods of achieving such a high density are described below in FIGS. 4A-5B. The TSM layer 312 has a thickness in the y-direction of about 100 Å to about 140 Å, such as about 120 Å.

The first migration barrier layer 306 may comprise a different material than the second migration barrier layer 308. The first and second migration barrier layers 306, 308, are not only effective at reducing elemental migration. Still, they are generally higher resistance layers that reduce electrical shunting between layers and serve to transfer the (100) or (110) epitaxial growth from one layer to the next, or to the topological SOT layers which lowers interfacial roughness. Barrier layers can be selected from 3 different nonmagnetic type material groups.

The first group of materials for the barrier layers 306 and 308 includes these options: (1) high lattice parameter, higher resistance, atomically ordered stoichiometric B2 (AB) binary alloys, such as RuHf and Zr-X alloys, where X is one or more of Co, Cu, Ru, and Rh; (2) Ti-Y alloys, where Y is one or more of Au, Ru, and Rh; or (3) stoichiometric B2 ternary A(BxC1-x) alloys, like (HfTi).5Ru, Ru(AlV).5, (AlMo).5Ti, and CoZrX, where X is one or more of Ti, Fe, Ni, Nb, and Mo (examples include (Co(Ti.3Zr.7), (Co.8Fe.2)Zr, (CoNi).5Zr, Co (Nb.25Zr.75)). The barrier layers 306, 308 can also be disordered nonstoichiometric binary, ternary, or higher bcc alloys where multiple elements are selected, to form a bcc alloy, from the group consisting of: Ta, Hf, W, Ir, Pt, Y, Zr, Nb, Mo, Mg, Sc, Ti, V, Cr, Fe, Co, Ni, Cu, Ru, Rh, and Ag, where all have lattice parameters in the range of 2.87 Å to 3.38 Å.

The second group of materials for the barriers layers 306 and 308 are fcc materials with lattice parameters about 4.08 Å to 4.75 Å, such as oxides of Ti, Mg, Ni, Zn, or Zr; or X-N or X-C composites where X is one or more of Sc, Ti, V, Cr, Zr, Nb, Ta, Hf, and W, as well as alloy composites of the above.

The third group of materials for the barrier layers 306 and 308 are tetragonal oxides with a-axis lattice parameters in a range of 4.35 Å to 4.75 Å and c-axis in the range of 2.85 Å to 3.19 Å, like MO₂ materials, examples of which include where M is Ti, Cr, Ru, Rh, Sn, Sb, or Ir; or CrNb, CrV, and WV alloys; or any combination thereof.

The first two barrier layer material groups can be used with either (100) or (110) texturing layers to form (100) or (110) textured barrier layers 306, 308. The texturing of the third group of barrier layer materials (i.e., the MO₂ tetragonal oxides) will depend on the texturing layer type. For (100) texturing layers, the MO₂ tetragonal oxides will produce (001) textured MO₂ tetragonal oxides, which in turn can be used to create (100) texture in other layers. With (110) texturing layers, the MO₂ tetragonal oxides will create a (110) textured tetragonal M0₂ oxide layer, but only for oxides where the a/c ratio is near the sqrt(2), such as where M is Os, Ir, Ru, Rh, or Pd. The first migration barrier layer 306 may comprise a different material than the second migration barrier layer 308. Each barrier layer 306 and 308 may comprise one or more barrier layers depending on the application to optimize growth, electrical shunting, or elemental migration properties between layers.

The seed layer 302 comprises an amorphous or nanocrystalline material. The seed layer 302 may comprise a laminated structure comprising one or more materials selected from the group consisting of NiTa, RuAl, MgO, MgTiO, CrMo, CoFeTa, NiFeGe, NiFeTa, NiW, Ru, IrAl, and combinations thereof. The seed layer 302 has a thickness in the y-direction of about 10 Å to about 30 Å, such as about 20 Å.

The buffer layer 304 may comprise a combination of materials selected from the groups consisting of (100) or (110) textured layers, or mixtures thereof, with the groups of (a)-(k) listed below: (a) bcc metals or alloys with a-axis lattice parameters in the range of 2.9 Å to about 3.4 Å, such as Ta, W, Mo, Nb, WTi, and CrMo; (b) B2 metals with the same lattice parameter range, such as binary alloys of RuAl, RuHf, Zr-X alloys, where X is one or more of Co, Cu, Ru, and Rh, or Ti-Y alloys where Y is one or more of Au, Ru, and Rh; (c) B2 ternary alloys like HfRuTi, RuAlV, AlTiMo, and CoZrX, where X is one or more of Ti, Fe, Ni, Nb, and Mo, or any combinations of the above; (d) (100) and (110) textured fcc materials with lattice parameters about 4.08 Å to about 4.75 Å, such as oxides of Ti, Mg, Ni, Zn, and Zr, X-N, or X-C composites, where X is one or more of Sc, Ti, V, Cr, Zr, Nb, Ta, Hf, and W, as well as alloy composites of the above; (e) (001) textured tetragonal oxides with a-axis lattice parameters in a similar range as above, such as MO₂ materials, where M is one or more of Ti, Cr, Ru, Rh, Sn, Sb, and Ir, or alloy composites thereof; (f) (110) textured tetragonal MO₂ where a/c ratio is near the sqrt(2), such as where M is one or more of Os, Ir, Ru, Rh, Sn, Sb, and Pd; (g) high lattice parameter fcc (110) or (100) textured Heusler alloys, either half metallic or full, with lattice parameters in the range of 5.9 Å to 6.7 Å, such as MnSbPt (6.20 Å) or Sc₂VGe (a=6.65 Å), and Pd₂SnY (6.70 Å); (h) other spinel cubic materials with the space group 216 and similar lattice parameters, such as YNiBi, YPdBi, NiBiGd, AgMgSb, and BiXPt (where X is a rare earth element from Gd to Lu); (i) (100) textured layer materials such as X-Al, where X is one or more of Co, Ni, Ru, Rh, and Ir; (j) heated Cr or CrX alloys, where X is one or more of Mo, Mn, Ti, Ru, and W; and (k) combinations thereof.

Those skilled in the art can grow bcc metals along the close-packed direction creating strong (110) textured bcc or bcc alloy films mentioned above with lattice parameters in the range of 2.9 Å to 3.4 Å range, using combinations of nanocrystalline conditioning layers and other bcc seed layer materials; alloys seed layer films, such as the Cr-X alloys mentioned above; or by using thin (001) hcp Ru seeds. These highly textured (110) bcc or bcc alloy films can then be used to grow fcc (110) textured buffer layer films with lattice parameters of about 4.08 Å to 4.75 Å mentioned; (110) textured binary or ternary or higher B2 alloys mentioned above; or high lattice parameter fcc Heuslers or spinels with lattice parameters in the range of about 5.9 Å to 6.7 Å mentioned above, which can be utilized as high resistance or migration buffers layers on which to grow (110) textured YPtBi SOT layers. (110) textured buffer layers of MO₂ oxides could also be used for those oxides that have a/c ratios near the sqrt(2), as mentioned above.

Those skilled in the art can also grow bcc metals or B2 materials and alloys with a strong (100) texture and lattice parameters in the range of about 2.9 Å to 3.4 Å, like those of RuAl or heated Cr-X alloys mentioned above. These (100) textured layers can be used to grow strong fcc (100) textured buffer layers with lattice parameters in the range of 4.08 Å to 4.75 Å mentioned above; (100) textured Heusler alloys or spinel-type structures with lattice parameters in the range of 5.9 Å to 6.75 Å mentioned above; or (001) textured MO₂ tetragonal oxides mentioned above with axis lattice parameters in the 4.1 Å to 4.75 Å range.

Buffer layers between the textured seed layers and the SOT layer can, in general, offer better control of electrical shunting between the seed layers and the SOT layer, or serve as migration barriers to prevent intermixing of the SOT layer and seed layers, or provide better film epitaxial growth to the YPtBi or BiSbX SOT layer.

The FM layer 316 has a thickness of about 5 Å to about 15 Å and may comprise NiFe, CoFe, NiFeX, CoFeX, FeX, or Nix, where X is one or more of Co, Ni, Cu, Si, Al, Mn, Ge, Ta, Hf, N, or B. The FM layer 316 may comprise any magnetic layer combination or alloy combination of these elements that can yield a low coercivity, negative magnetostrictive FM layer 316, or in multilayer combinations with other higher polarizing materials like Heusler alloys or high Ni-containing alloy FM layers. The sub-interlayer 314 may comprise MgO, CoFeB, Co, CoFe, NiFe, or a similar material as the FM layer 316. The sub-interlayer 314 and the interlayer 310 collectively have a thickness in the y-direction of about 20 Å or less.

The cap layer 318 may comprise nonmagnetic, high resistivity materials, such as: thin ceramic oxides or nitrides of TiN, SiN, MgTiO, and MgO; amorphous/nanocrystalline metals such as NiFeGe, NiFeTa, NiTa, NiHf, NiFeHf, CoHf, CoFeHf, NiWTa, NiFeW, NiW, WRe; or nitrides, oxides, or borides of elements as mentioned earlier, compounds, and/or alloys such as NiTaN, NiFeTaN, NiWTaN, NiWN, WReN, TaN, WN, TaOx, WOx, WB, HfB, NiHfB, NiFeHfB, CoHfB, and CoFeHfB, where x is a numeral. In some embodiments, lower atomic number (Z) materials are preferred in the cap layer 318 to reduce sputter intermixing with the FM layer 316. High Z alloys can be used, if combined with a migration barrier beneath, or if the high Z elements are used with a high resistive oxide, nitride, or boride. The cap layer 318 can comprise multilayer combinations of the materials as mentioned earlier, and the overall thickness of the cap layer 318 is less than or equal to about 100 Å (nominally about 15 Å to about 50 Å).

FIGS. 4A-4C illustrate methods 400, 430, and 450, respectively, of forming YPtBi having a 1:1:1 composition, according to various embodiments. The methods 400, 430, and 450 may each be used to create the TSM layer 312 or FIGS. 3A-3B.

In the method 400 of FIG. 4A, at block 402, a substrate is loaded onto a chuck heated to a temperature of about 300° C. to about 600° C. in a deposition chamber. The deposition chamber may be any known deposition chamber, such as a physical vapor deposition (PVD) chamber.

At block 404, one of the following target combinations is placed in the deposition chamber: 1) a YPt target and a Bi target; 2) a YBi target and a Bi target; or 3) PtBi target and a Y target. The targets may not be 50/50 targets due to preferential sputtering of Bi. As such, the targets may contain less Bi than about 50%. At block 406, the Kr, Ar, or Xe gas flow, pressure, and substrate bias within the deposition chamber are adjusted. The Kr, Ar, or Xe gas flow may be about 25 sccm to about 55 sccm, such as about 40 sccm. The pressure may be about 0.2 mtorr to about 20 mtorr, or about 0.2 mtorr or less, while holding a stable plasma. The substrate bias may be about 20 V to about 200 V, such as about 50 V±25 V.

At block 408, power and Kr, Ar, or Xe gas are applied to the selected targets to sputter the targets on the substrate to form a film comprising YPtBi having a 1:1:1 stoichiometry or composition. Different power levels may be applied to each target when sputtering. For example, when a YPt target and a Bi target are selected, a first power of about 90 W to about 200 W may be used when sputtering the YPt target, and a second power of about 20 W to about 50 W may be used when sputtering the Bi target. In some embodiments, the power applied to the Bi target is about 20% to about 30% of the power applied to the YPt target, or a ratio of about 5:1 for the YPt target to the Bi target.

Utilizing different power levels, and adjusting the Kr, Ar, or Xe gas flow, enables the YPtBi film to achieve a 1:1:1 stoichiometry and a high density between about 9.7 g/cc to about 11.2 g/cc. In some embodiments, the density of the YPtBi film is greater than about 11 g/cc. Moreover, trace amounts of Kr are detectable in the completed film. For example, about 0.5 at. % to about 2.0 at. % of Kr, Ar, or Xe may be detectable as a dopant.

In the method 430 of FIG. 4B, at block 432, a substrate is loaded onto a chuck heated to a temperature of about 300° C. to about 600° C. in a deposition chamber. The deposition chamber may be any known deposition chamber, such as a physical vapor deposition (PVD) chamber.

At block 434, a Y target, a Pt target, and a Bi target are placed in the deposition chamber. At block 436, the gas flow, pressure, and substrate bias within the deposition chamber are adjusted. The gas flow may be about 25 sccm to about 55 sccm, such as about 40 sccm. The pressure may be about 0.2 mtorr to about 20 mtorr, or about 0.2 mtorr or less, while holding a stable plasma. The substrate bias may be about 20 V to about 200 V, such as about 50 V±25 V. At block 438, power and Kr, Ar, or Xe gas are applied to the Y, Pt, and Bi targets to sputter the targets on the substrate to form a film comprising YPtBi having a 1:1:1 stoichiometry or composition. Different power levels may be applied to each target when sputtering. For example, a first power of about 100 W to about 500 W, such as about 115 W to about 125 W, may be used when sputtering the Y target, a second power of about 20 W to about 300 W, such as about 25 W to about 30 W when sputtering the Bi target, and a third power of about 20 W to about 500 W may be used when sputtering the Pt target. In some embodiments, the power applied to the Pt target is about 20% to about 30% of the power applied to the YBi target.

Utilizing different power levels, and adjusting the Kr, Ar, or Xe gas flow, enables the YPtBi film to achieve a 1:1:1 stoichiometry and a high density between about 9.7 g/cc to about 11.2 g/cc. In some embodiments, the density of the YPtBi film is greater than about 11 g/cc. Moreover, trace amounts of Kr are detectable in the completed film. For example, about 0.1 at. % to about 2.5 at. % of Kr, Ar, or Xe may be detectable as a dopant.

In the method 450 of FIG. 4C, at block 452, a substrate is loaded onto a chuck heated to a temperature of about 300° C. to about 600° C. in a deposition chamber. The deposition chamber may be any known deposition chamber, such as a physical vapor deposition (PVD) chamber.

At block 454, a YPtBi target is placed in the deposition chamber. For example, to form the YPtBi target, the following amounts may be used: about 10 grams (g) to about 15 g of Y, about 20 g to about 30 g of Pt, and about 20 g to about 40 g of Bi. At block 456, the gas flow, pressure, and substrate bias within the deposition chamber are adjusted. The gas flow may be about 25 sccm to about 55 sccm, such as about 40 sccm. The pressure may be about 0.2 mtorr to about 20 mtorr, or about 0.2 mtorr or less, while holding a stable plasma. The substrate bias may be about 20 V to about 200 V, such as about 50 V±25 V.

At block 458, power and Kr, Ar, or Xe gas are applied to the YPtBi target to sputter the targets on the substrate to form a film comprising YPtBi having a 1:1:1 stoichiometry or composition. The power applied to the YPtBi target may be about 20 W to about 500 W. Adjusting the power level and the gas flow enables the YPtBi film to achieve a 1:1:1 stoichiometry and a high density between about 9.7 g/cc to about 11.2 g/cc. In some embodiments, the density of the YPtBi film is greater than about 11 g/cc. Moreover, trace amounts of Kr, Ar, or Xe are detectable in the completed film. For example, about 0.1 at. % to about 2.5 at. % of Kr, Ar, or Xe may be detectable as a dopant.

FIG. 5A illustrates a graph 500 showing that, in order to read a 1:1:1 composition, the power ratio between the power (W) applied to the Bi target versus the power (W) applied to the YPt target is fixed, according to one embodiment. FIG. 5B illustrates a graph 550 showing the stoichiometry of YPt difference between Pt and Y in a sputtered YPtBi film is controlled by the Kr gas flow (sccm), according to one embodiment. While the graphs 500 and 550 correspond to the method 400 of FIG. 4A using a YPt target and a Bi target, the graphs are merely intended to be examples, and may apply to the methods 430 and 450 of FIGS. 4B-4C. Kr gas is used as an example, but the gas may be Ar or Xe as well.

As shown in the graphs 500 and 550, when a YPtBi film is deposited at a Kr gas flow of about 40 sccm and a power of about 20 W to about 45 W is applied to the Bi target, and a power of about 90 W to about 200 W is applied to the YPt (50/50) target, the resulting YPtBi having a 1:1:1 stoichiometry achieves a high density between about 9.7 g/cc to about 11.2 g/cc.

Also shown in the graph 550, a 1:1 relative Y to Pt stoichiometry is achieved in a YPtBi film for a non-stoichiometry YPt (49/51) target (a ±2% delta) when the Kr gas flow is between about 15 sccm to about 55 sccm, such as about 15 sccm, when the powers of Bi and YPt from the graph 500 are applied to Bi and YPt targets, respectively.

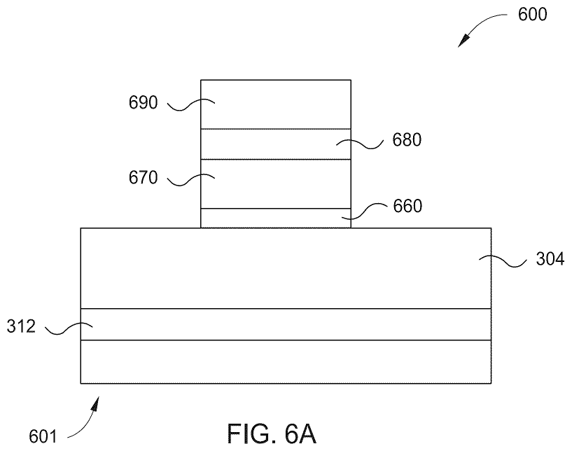

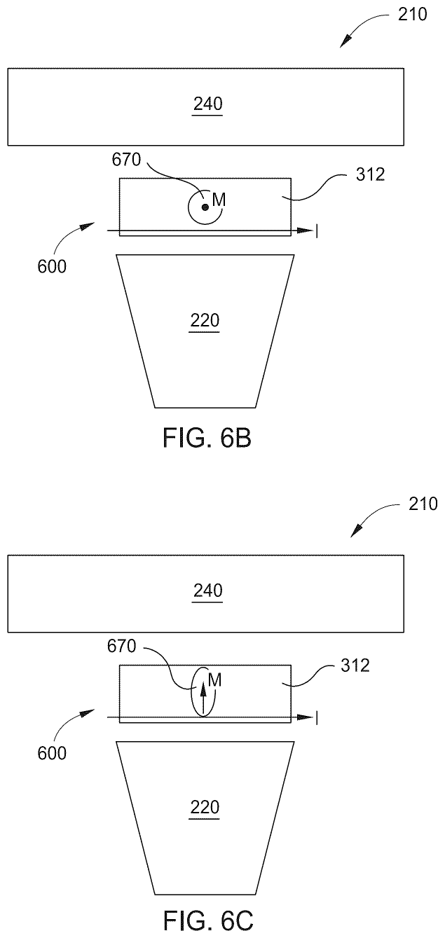

FIG. 6A is a schematic cross-sectional view of a SOT device 600 for use in a MAMR magnetic recording head, such as the MAMR magnetic recording head of the drive 100 of FIG. 1 or other suitable magnetic media drives. The SOT device 600 comprises a TSM layer 312 orientation formed over a buffer layer 304 formed over a substrate 601, such as the TSM layer 312 and the buffer layer 304 of FIG. 3A or the TSM layer 312 and the buffer layer 304 of FIG. 3B. Thus, the TSM layer 312 may comprise YPtBi having a (100) orientation or YPtBi having a (110) orientation. A spin torque layer (STL) 670 is formed over the TSM layer 312. The STL 670 comprises a ferromagnetic material such as one or more layers of CoFe, Colr, NiFe, and CoFeX alloy wherein X=B, Ta, Re, or Ir.

In certain embodiments, an electrical current shunt block layer 660 is disposed between the TSM layer 312 and the STL 670. The electrical current shunt blocking layer 660 reduces electrical current from flowing from the TSM layer 312 to the STL 670 but allows spin orbital coupling of the TSM layer 312 and the STL 670. In certain embodiments, the electrical current shunt blocking layer 660 comprises a magnetic material that provides greater spin orbital coupling between the TSM layer 312 and the STL 670 than a nonmagnetic material. In certain embodiments, the electrical current shunt blocking layer 660 comprises a magnetic material of FeCo, FeCOM, FeCOMO, FeCoMMeO, FeCOM/MeO stack, FeCoMNiMnMgZnFeO, FeCOM/NiMnMgZnFeO stack, multiple layers/stacks thereof, or combinations thereof in which M is one or more of B, Si, P, Al, Hf, Zr, Nb, Ti, Ta, Mo, Mg, Y, Cu, Cr, and Ni. Me is one or more of Si, Al, Hf, Zr, Nb, Ti, Ta, Mg, Y, or Cr. In certain embodiments, the electrical current shunt blocking layer 660 is formed to a thickness from about 10 Å to about 100 Å. In certain aspects, an electrical current shunt blocking layer 660 with a thickness of over 100 Å may reduce the spin-orbital coupling of the TSM layer 312 and the STL 670. In certain aspects, an electrical current shunt blocking layer having a thickness of less than 10 Å may not sufficiently reduce electrical current from TSM layer 312 to the STL 670.

In certain embodiments, additional layers are formed over the STL 670 such as a spacer layer 680 and a pinning layer 690. The pinning layer 690 can partially pin the STL 670. The pinning layer 690 comprises a single or multiple layers of PtMn, NiMn, IrMn, IrMnCr, CrMnPt, FeMn, other antiferromagnetic materials, or combinations thereof. The spacer layer 580 comprises single or multiple layers of magnesium oxide, aluminum oxide, other nonmagnetic materials, or combinations thereof.

FIGS. 6B-6C are schematic MFS views of certain embodiments of a portion of a MAMR magnetic recording head 210 with a SOT device 600 of FIG. 6A. The MAMR magnetic recording head 210 can be the magnetic recording head FIG. 2 or other suitable magnetic recording heads in the drive 100 of FIG. 1 or other suitable magnetic media drives such as tape drives. The MAMR magnetic recording head 210 includes a main pole 220 and a trailing shield 240 in a track direction. The SOT device 600 is disposed in a gap between the main pole and the trailing shield 240.

While the MRAM device 600 generally corresponds to the top-SOT embodiments of FIG. 3B, other MRAM implementations (where the layers of MRAM device 600 are reversed) can correspond or conform to the bottom-SOT embodiments of FIG. 3A. The TSM layer 312, the RL 610, and the buffer layer 302 in FIG. 6 may correspond to various layer configurations in FIGS. 3A-3B. For example, the TSM layer 312 can correspond to the TSM layer 312. Thus, the TSM layer 312 may comprise YPtBi having a (100) orientation or YPtBi having a (110) orientation. The RL 610 may correspond to the FM layer 316. The buffer layer 304 may correspond to the buffer layer 304.

During operation, charge current through a TI layer or layer stack 312 acting as a spin Hall layer generates a spin current in the BiSb layer. The spin orbital coupling of the BiSb layer and a spin torque layer (STL) 670 causes switching or precession of magnetization of the STL 670 by the spin orbital coupling of the spin current from the TSM layer 312. Switching or precession of the magnetization of the STL 670 can generate an assisting AC field to the write field. Energy-assisted magnetic recording heads based on SOT have multiple times greater power efficiency than MAMR magnetic recording heads based on spin transfer torque. As shown in FIG. 6B, an easy axis of a magnetization direction of the STL 670 is perpendicular to the MFS from shape anisotropy of the STL 670, from the pinning layer 690 of FIG. 6A, and/or from hard bias elements proximate to the STL 670. As shown in FIG. 6C, an easy axis of a magnetization direction of the STL 670 is parallel to the MFS from shape anisotropy of the STL 670, from the pinning layer 690 of FIG. 6A, and/or from complex bias elements proximate to the STL 670.

FIG. 7 is a schematic cross-sectional view of an SOT MTJ 701 used as a MRAM device 700. The MRAM device 700 comprises a reference layer (RL) 710, a spacer layer 720 over the RL 710, a recording layer 730 over the spacer layer 720, a buffer layer 704 over an electrical current shunt block layer 740 over the recording layer 630, and a TI layer or layer stack 312 over the buffer layer 304. The TSM layer 312 and the buffer layer 304 may be the TSM layer 312 and the buffer layer 304 of FIG. 3A or the TI layer 332 and the buffer layer 360 of FIG. 3B. Thus, the TSM layer 312 may comprise YPtBi having a (100) orientation or YPtBi having a (110) orientation.

The RL 710 comprises single or multiple layers of CoFe, other ferromagnetic materials, and combinations thereof. The spacer layer 720 comprises single or multiple layers of magnesium oxide, aluminum oxide, other dielectric materials, or combinations thereof. The recording layer 730 comprises single or multiple layers of CoFe, NiFe, other ferromagnetic materials, or combinations thereof.

As noted above, in certain embodiments, the electrical current shunt block layer 740 is disposed between the buffer layer 304 and the recording layer 730. The electrical current shunt blocking layer 740 reduces electrical current from flowing from the TSM layer 312 to the recording layer 730. The electrical current shunt blocking layer 740 still allows spin orbital coupling of the TSM layer 312 and the recording layer 730. For example, writing to the MRAM device can be enabled by the spin orbital coupling of the TSM layer and the recording layer 730, which allows switching of magnetization of the recording layer 730 by the spin orbital coupling of the spin current from the TSM layer 312. In certain embodiments, the electrical current shunt blocking layer 740 comprises a magnetic material that provides greater spin orbital coupling between the TSM layer 312 and the recording layer 730 than a nonmagnetic material. In certain embodiments, the electrical current shunt blocking layer 740 comprises a magnetic material of FeCOM, FeCOMO, FeCoMMeO, FeCOM/MeO stack, FeCoMNiMnMgZnFeO, FeCOM/NiMnMgZnFeO stack, multiple layers/stacks thereof, or combinations thereof, in which M is one or more of B, Si, P, Al, Hf, Zr, Nb, Ti, Ta, Mo, Mg, Y, Cu, Cr, and Ni; and Me is Si, Al, Hf, Zr, Nb, Ti, Ta, Mg, Y, or Cr.

The MRAM device 700 of FIG. 7 may include other layers, such as pinning layers, pinning structures (e.g., a synthetic antiferromagnetic (SAF) pinned structure), electrodes, gates, and other structures. Other MRAM devices besides the structure of FIG. 6 can be formed utilizing a TSM layer 312 over a buffer layer 304 to form a SOT MTJ 701.

Therefore, high spin Hall angles can be achieved by utilizing a YPtBi film having a 1:1:1 stoichiometry and a high density of about 9.7 g/cc to about 11.2 g/cc in an SOT device.

In one embodiment, a spin-orbit torque (SOT) device comprises a YPtBi layer having a 1:1:1 stoichiometry, the YPtBi layer having a density between about 9.7 g/cc to about 11.2 g/cc.

The YPtBi layer comprises about 0.1 at. % to about 2.5 at. % of Kr, Ar, or Xe. The YPtBi layer has a (100), (111), or (110) orientation. The SOT device further comprises a buffer layer disposed adjacent to the YPtBi layer. The buffer layer comprises a material selected from the group consisting of: X-Al, where X is one or more of Co, Ni, Ru, Rh, and Ir; Cr or CrX alloys, where X is one or more of Mo, Mn, Ti, Ru, and W; and RuAl, W-X, or Ta-X alloys with MgO and TiO, where X is one or more of Ta, Hf, W, V, Ti, Nb and Mo. The buffer layer comprises a material selected from the group consisting of: RuHf; Zr-X alloys, where X is one or more of Co, Cu, Ru, and Rh; Ti-Y alloys, where Y is one or more of Au, Ru, and Rh; B2 ternary A(BxC1-x) alloys; B2 binary alloys; CoZrX, where X is one or more of Ti, Fe, Ni, Nb, and Mo; two or more elements selected from the group consisting of: Ta, Hf, W, Ir, Pt, Y, Zr, Nb, Mo, Mg, Sc, Ti, V, Cr, Fe, Co, Ni, Cu, Ru, Rh, and Ag; oxides of Ti, Mg, Ni, Zn, or Zr; X-N or X-C composites, where X is one or more of Sc, Ti, V, Cr, Zr, Nb, Ta, Hf, and W; and MO₂ materials, where M is one or more of Ti, Cr, Ru, Rh, Sn, Sb, Ir, CrNb, CrV, and WV. A magnetic recording head comprises the SOT device. A magnetic recording device comprises the magnetic recording. A magnetoresistive memory comprises the SOT device.

In another embodiment, a method of forming a YPtBi film having a 1:1:1 stoichiometry comprises loading a substrate onto a chuck heated to a temperature of about 300° C. to about 600° C. in a deposition chamber, placing a YPt target and a Bi target in the deposition chamber, adjusting a Kr, Ar, or Xe gas flow, pressure, and substrate bias of the deposition chamber, and applying power and Kr, Ar, or Xe gas to sputter the YPt target and the Bi target to form a film comprising YPtBi film having a 1:1:1 stoichiometry.

A first power is applied to sputter the YPt target and a second power is applied to sputter the Bi target. The first power is greater than the second power. The second power is about 20% to about 30% of the first power. The Kr, Ar, or Xe gas flow is about 20 sccm to about 50 sccm. The YPtBi film having a 1:1:1 stoichiometry has a density between about 9.7 g/cc to about 11.2 g/cc. A spin-orbit torque (SOT) device comprises the YPtBi film having a 1:1:1 stoichiometry formed from the method.

In yet another embodiment, a method of forming a YPtBi film having a 1:1:1 stoichiometry comprises loading a substrate onto a chuck heated to a temperature of about 300° C. to about 600° C. in a deposition chamber, placing one of the following target combinations in the deposition chamber: 1) a YBi target and a Pt target; 2) a PtBi target and a Y target; or a Y target, a Pt target, anda Bi target, adjusting a Kr, Ar, or Xe gas flow, pressure, and substrate bias of the deposition chamber, and applying power and Kr, Ar, or Xe gas to sputter the YBi target and the Pt target to form a film comprising YPtBi film having a 1:1:1 stoichiometry.

The pressure is about 0.2 mtorr to about 20 mtorr. The substrate bias is about 25 V to about 75 V. The Kr, Ar, or Xe gas flow is about 20 sccm to about 50 sccm. The YPtBi film having a 1:1:1 stoichiometry has a density between about 9.7 g/cc to about 11.2 g/cc. A spin-orbit torque (SOT) device comprises the YPtBi film having a 1:1:1 stoichiometry formed from the method.

While the preceding is directed to embodiments of the present disclosure, other and further embodiments of the disclosure may be devised without departing from the basic scope thereof, and the scope thereof is determined by the following claims.

What is claimed is:

1. A spin-orbit torque (SOT) device, comprising:
a YPtBi layer having a 1:1:1 stoichiometry, the YPtBi layer having a density between about 9.7 g/cc to about 11.2 g/cc.

2. The SOT device of claim 1, wherein the YPtBi layer comprises about 0.1 at. % to about 2.5 at. % of Kr, Ar, or Xe.

3. The SOT device of claim 1, wherein the YPtBi layer has a (100), (111), or (110) orientation.

4. The SOT device of claim 1, further comprising a buffer layer disposed adjacent to the YPtBi layer.

5. The SOT device of claim 4, wherein the buffer layer comprises a material selected from the group consisting of:
X-Al, where X is one or more of Co, Ni, Ru, Rh, and Ir;
Cr or CrX alloys, where X is one or more of Mo, Mn, Ti, Ru, and W; and
RuAl, W-X, or Ta-X alloys with MgO and TiO, where X is one or more of Ta, Hf, W, V, Ti, Nb and Mo.

6. The SOT device of claim 4, wherein the buffer layer comprises a material selected from the group consisting of:
RuHf;
Zr-X alloys, where X is one or more of Co, Cu, Ru, and Rh;
Ti-Y alloys, where Y is one or more of Au, Ru, and Rh;
B2 ternary A(BxC1-x) alloys;
B2 binary alloys;
CoZrX, where X is one or more of Ti, Fe, Ni, Nb, and Mo;
two or more elements selected from the group consisting of: Ta, Hf, W, Ir, Pt, Y, Zr, Nb, Mo, Mg, Sc, Ti, V, Cr, Fe, Co, Ni, Cu, Ru, Rh, and Ag;
oxides of Ti, Mg, Ni, Zn, or Zr;
X-N or X-C composites, where X is one or more of Sc, Ti, V, Cr, Zr, Nb, Ta, Hf, and W; and
MO₂ materials, where M is one or more of Ti, Cr, Ru, Rh, Sn, Sb, Ir, CrNb, CrV, and WV.

7. A magnetic recording head comprising the SOT device of claim 1.

8. A magnetic recording device comprising the magnetic recording head of claim 7.

9. A magnetoresistive memory comprising the SOT device of claim 1.

10. A method of forming a YPtBi film having a 1:1:1 stoichiometry, the method comprising:
loading a substrate onto a chuck heated to a temperature of about 300° C. to about 600° C. in a deposition chamber;
placing a YPt target and a Bi target in the deposition chamber;
adjusting a Kr, Ar, or Xe gas flow, pressure, and substrate bias of the deposition chamber; and
applying power and Kr, Ar, or Xe gas to sputter the YPt target and the Bi target to form a film comprising YPtBi film having a 1:1:1 stoichiometry and a density between about 9.7 g/cc to about 11.2 g/cc.

11. The method of claim 10, wherein a first power is applied to sputter the YPt target and a second power is applied to sputter the Bi target.

12. The method of claim 11, wherein the first power is greater than the second power.

13. The method of claim 11, wherein the second power is about 20% to about 30% of the first power.

14. The method of claim 10, wherein the Kr, Ar, or Xe gas flow is about 20 sccm to about 50 sccm.

15. A spin-orbit torque (SOT) device comprising the YPtBi film having a 1:1:1 stoichiometry formed from the method of claim 10.

16. A method of forming a YPtBi film having a 1:1:1 stoichiometry, the method comprising:
loading a substrate onto a chuck heated to a temperature of about 300° C. to about 600° C. in a deposition chamber;
placing one of the following target combinations in the deposition chamber:
a YBi target and a Pt target;
a PtBi target and a Y target; or
a Y target, a Pt target, and a Bi target;
adjusting a Kr, Ar, or Xe gas flow, pressure, and substrate bias of the deposition chamber; and
applying power and Kr, Ar, or Xe gas to sputter the YBi target and the Pt target to form a film comprising YPtBi film having a 1:1:1 stoichiometry and a density between about 9.7 g/cc to about 11.2 g/cc.

17. The method of claim 16, wherein the pressure is about 0.2 mtorr to about 20 mtorr.

18. The method of claim 16, wherein the substrate bias is about 25 V to about 75 V.

19. The method of claim 16, wherein the Kr, Ar, or Xe gas flow is about 20 sccm to about 50 sccm.

20. A spin-orbit torque (SOT) device comprising the YPtBi film having a 1:1:1 stoichiometry formed from the method of claim 16.
